(19) United States
(12) Patent Application Publication
(10) Pub. No.: US 2026/0198061 A1
(43) Pub. Date: Jul. 9, 2026

(54) AIR SPACER WITH LINER FOR SEMICONDUCTOR DEVICES

(71) Applicant: Taiwan Semiconductor Manufacturing Company, Ltd., Hsinchu (TW)

(72) Inventors: Yu-Lun Chiu, Taichung City (TW); Chih-Ying Chen, Pingtung (TW); Chi-Ruei Yeh, New Taipei City (TW); Tsung-Yu Chiang, New Taipei City (TW)

(73) Assignee: Taiwan Semiconductor Manufacturing Company, Ltd., Hsinchu (TW)

(21) Appl. No.: 19/015,379

(22) Filed: Jan. 9, 2025

(51) Int. Cl. H10D 64/23; H10D 64/01

(52) U.S. Cl. CPC H10D 64/256; H10D 64/021

(57) ABSTRACT

The present disclosure describes a semiconductor device having an air spacer with a liner protecting a source/drain (S/D) structure. The semiconductor device includes a S/D structure on a substrate, a gate structure on the substrate and adjacent to the S/D structure, a gate capping structure on the gate structure, a contact structure on the S/D structure and adjacent to the gate structure, a liner on sidewall surfaces of the gate capping structure and top surfaces of the S/D structure, and a spacer layer on sidewall surfaces of the contact structure. An air gap is enclosed by the spacer layer and the liner.

### BACKGROUND

With advances in semiconductor technology, there has been increasing demand for higher storage capacity, faster processing systems, higher performance, and lower costs. To meet these demands, the semiconductor industry continues to scale down the dimensions of semiconductor devices, such as metal oxide semiconductor field effect transistors (MOSFETs), including planar MOSFETs and fin field effect transistors (FinFETs), gate-all-around field effect transistors (GAAFETs), complementary field effect transistors (CFETs), nanosheet transistors, nanowire transistors, multi-bridge channel transistors, nano-ribbon transistors, and other similar structured transistors. Such scaling down has increased the complexity of semiconductor manufacturing processes and increased the difficulty of defect control in the semiconductor devices.

### BRIEF DESCRIPTION OF THE DRAWINGS

Aspects of the present disclosure are best understood from the following detailed description when read with the accompanying figures.

FIG. 1 illustrates an isometric view of a semiconductor device having an air spacer with a liner protecting a source/drain structure, in accordance with some embodiments.

FIG. 2 illustrates a partial cross-sectional view of a semiconductor device having an air spacer with a liner protecting a source/drain structure, in accordance with some embodiments.

FIG. 3 is a flow diagram of a method for fabricating a semiconductor device having an air spacer with a liner protecting a source/drain structure, in accordance with some embodiments.

FIGS. 4-11 illustrate partial isometric and cross-sectional views of a semiconductor device having an air spacer with a liner protecting a source/drain structure at various stages of its fabrication, in accordance with some embodiments.

Illustrative embodiments will now be described with reference to the accompanying drawings. In the drawings, like reference numerals generally indicate identical, functionally similar, and/or structurally similar elements.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over a second feature in the description that follows may include embodiments in which the first and second features are formed in direct contact, and may also include embodiments in which additional features may be formed between the first and second features, such that the first and second features may not be in direct contact. As used herein, the formation of a first feature on a second feature means the first feature is formed in direct contact with the second feature. In addition, the present disclosure may repeat reference numerals and/or letters in the various examples. This repetition does not in itself dictate a relationship between the various embodiments and/or configurations discussed.

Further, spatially relative terms, such as “beneath,” “below,” “lower,” “above,” “upper,” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

It is noted that references in the specification to “one embodiment,” “an embodiment,” “an example embodiment,” “exemplary,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of one skilled in the art to effect such feature, structure or characteristic in connection with other embodiments whether or not explicitly described.

It is to be understood that the phraseology or terminology herein is for the purpose of description and not of limitation, such that the terminology or phraseology of the present specification is to be interpreted by those skilled in relevant art(s) in light of the teachings herein.

In some embodiments, the terms “about” and “substantially” can indicate a value of a given quantity that varies within 20 % of the value (e.g., ±1 %, ±2 %, ±3 %, ±4 %, ±5 %, ±10 %, ±20 % of the value). These values are merely examples and are not intended to be limiting. The terms “about” and “substantially” can refer to a percentage of the values as interpreted by those skilled in relevant art(s) in light of the teachings herein.

With increasing demand for lower power consumption, higher performance, and smaller semiconductor devices, dimensions of semiconductor devices continue to scale down. The continuous scaling down of device dimensions and the increasing demand for device performance may require various process and material improvements, which can have multiple challenges. For example, replacing a dielectric layer with an air spacer between a gate structure and a source/drain (S/D) contact structure of a semiconductor device can reduce parasitic capacitance and improve reliability of the semiconductor device. However, during the formation of the air spacer, S/D structure of the semiconductor device can be exposed and damaged. As a result, the yield of the semiconductor device can be reduced.

Various embodiments in the present disclosure provide methods for forming an air spacer with a liner protecting a source/drain structure in a semiconductor device (e.g., a nanostructure transistor) and/or other semiconductor devices in an integrated circuit (IC). In some embodiments, a semiconductor device can include a channel structure on a substrate. An S/D structure can be in contact with the channel structure and a gate structure can be disposed on the channel structure. A gate spacer can be disposed on sidewall surfaces of the gate structure. A gate capping structure can be disposed on the gate structure. A liner can be disposed on top surfaces of the S/D structure and sidewall surfaces of the gate spacer and the gate capping structure. A contact structure can be disposed on the S/D structure and adjacent to the gate structure. A spacer layer can be disposed on sidewall surfaces of the contact structure. The liner and the spacer layer can enclose an air gap between the gate structure and the contact structure. In some embodiments, the liner can separate the air spacer from the S/D structure to avoid damage to the S/D structure during the formation of the air spacer. In some embodiments, with the liner protecting the S/D structure, both the reliability and the yield of the semiconductor device can be improved.

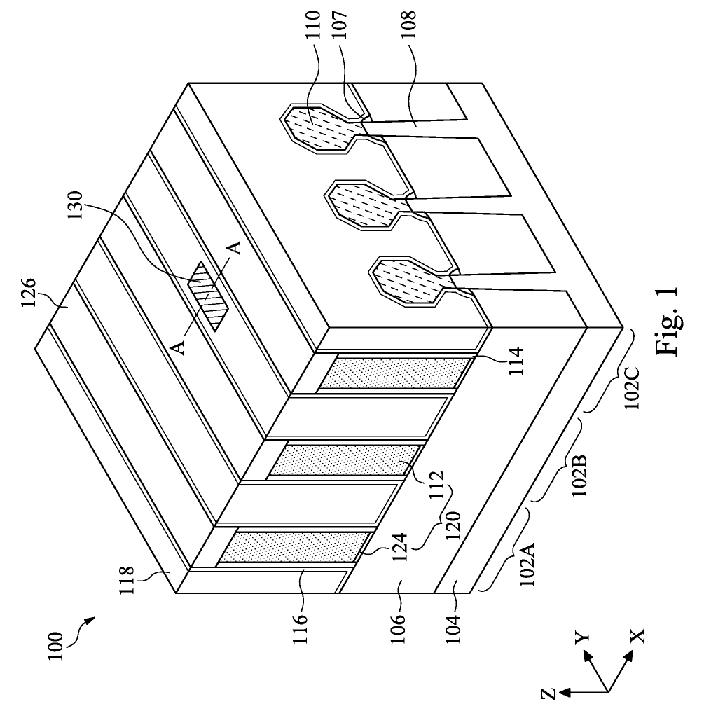

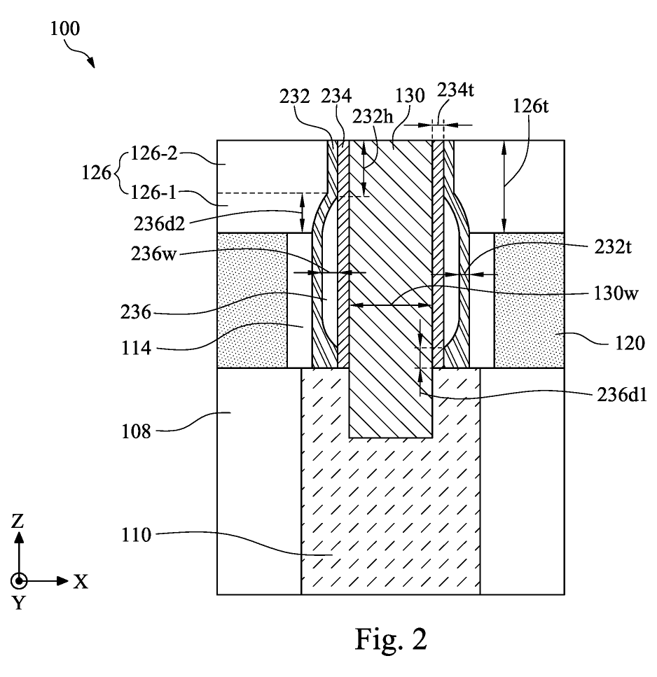

FIG. 1 illustrates an isometric view of a semiconductor device 100 having an air spacer with a liner protecting a S/D structure, in accordance with some embodiments. FIG. 2 illustrate a partial cross-sectional view of semiconductor device 100 across line A-A shown in FIG. 1, in accordance with some embodiments. In some embodiments, semiconductor device 100 can include transistors 102A-102C, as shown in FIG. 1. In some embodiments, transistors 102A-102C can include nanostructure transistors. The nanostructure transistors can include FinFETs, gate-all-around field effect transistors (GAA FETs), nanosheet transistors, nanowire transistors, multi-bridge channel transistors, nano-ribbon transistors, and other similar structured transistors.

In some embodiments, transistors 102A-102C can be n-type field-effect transistors (NFETs). In some embodiments, transistors 102A-102C can be p-type field-effect transistors (PFETs). In some embodiments, any of transistors 102A-102C can be an NFET or a PFET. Though FIG. 1 shows three transistors, semiconductor device 100 can have any number of transistors. In addition, semiconductor device 100 can be incorporated into an IC through the use of other structural components, such as conductive vias, conductive lines, dielectric layers, passivation layers, and interconnects, which are not shown for simplicity. The discussion of elements of transistors 102A-102C with the same annotations applies to each other, unless mentioned otherwise. And like reference numerals generally indicate identical, functionally similar, and/or structurally similar elements.

Referring to FIGS. 1 and 2, semiconductor device 100 having transistors 102A-102C can be formed on a substrate 104 and can be isolated by shallow trench isolation (STI) regions 106. Each of transistors 102A-102C can include fin structures 108, S/D structures 110, gate structures 120, sidewall spacers 107, gate spacers 114, and gate capping structures 126.

Referring to FIGS. 1 and 2, substrate 104 can include a semiconductor material, such as silicon. In some embodiments, substrate 104 includes a crystalline silicon substrate (e.g., wafer). In some embodiments, substrate 104 includes (i) an elementary semiconductor, such as germanium; (ii) a compound semiconductor including silicon carbide, gallium arsenide, gallium phosphide, indium phosphide, indium arsenide, and/or indium antimonide; (iii) an alloy semiconductor including silicon germanium carbide, silicon germanium, gallium arsenic phosphide, and/or aluminum gallium arsenide; or (iv) a combination thereof. Further, substrate 104 can be doped depending on design requirements (e.g., p-type substrate or n-type substrate). In some embodiments, substrate 104 can be doped with p-type dopants (e.g., boron, indium, aluminum, or gallium) or n-type dopants (e.g., phosphorus or arsenic).

STI regions 106 can provide electrical isolation between transistors 102A-102C and from neighboring transistors (not shown) on substrate 104 and/or neighboring active and passive elements (not shown) integrated with or deposited on substrate 104. STI regions 106 can be made of a dielectric material. In some embodiments, STI regions 106 can include silicon oxide, silicon nitride, silicon oxynitride, fluorine-doped silicate glass (FSG), a low-k dielectric material, and/or other suitable insulating materials. In some embodiments, STI regions 106 can include a multi-layered structure.

Referring to FIGS. 1 and 2, fin structures 108 can be formed on patterned portions of substrate 104. Embodiments of the fin structures disclosed herein may be patterned by any suitable method. For example, the fin structures may be patterned using one or more photolithography processes, including double-patterning or multi-patterning processes. Double-patterning or multi-patterning processes can combine photolithography and self-aligned processes, forming patterns that have, for example, pitches smaller than what is otherwise obtainable using a single, direct photolithography process. For example, a sacrificial layer is formed over a substrate and patterned using a photolithography process. Spacers can be formed alongside the patterned sacrificial layer using a self-aligned process. The sacrificial layer is then removed, and the remaining spacers can then be used to pattern the fin structures.

As shown in FIGS. 1 and 2, fin structures 108 can extend along an X-axis for transistors 102A-102C. In some embodiments, fin structures 108 can be disposed on substrate 104. Each of fin structures 108 can act as a channel structure and can form a channel region underlying gate structures 120 of transistors 102A-102C. In some embodiments, as shown in FIG. 2, fin structures 108 under gate structures 120 can form channel regions of semiconductor device 100. In some embodiments, fin structures 108 can include semiconductor materials similar to or different from substrate 104. In some embodiments, fin structures 108 can include silicon. The semiconductor materials of fin structures 108 can be undoped or can be in-situ doped during their formation process.

Referring to FIGS. 1 and 2, gate structures 120 can include gate dielectric layer 124 and gate electrode 112. In some embodiments, gate dielectric layer 124 can be formed on fin structures 108 and STI regions 106. In some embodiments, gate dielectric layer 124 can be multi-layered structures and can include an interfacial layer and a high-k dielectric layer. In some embodiments, gate dielectric layer 124 can include no interfacial layer and a high-k dielectric layer in direct contact with fin structures 108. In some embodiments, the interfacial layer can include silicon oxide formed by a deposition process or an oxidation process. In some embodiments, the interfacial layer can have a thickness ranging from about 0.1 nm to about 1.5 nm. In some embodiments, the high-k dielectric layer can include hafnium oxide, zirconium oxide, or other suitable high-k dielectric materials.

In some embodiments, as shown in FIGS. 1 and 2, gate electrode 112 can be disposed on gate dielectric layer 124. In some embodiments, gate electrode 112 can include one or more work function metal layers and a metal fill. The one or more work function metal layers can include work function metals to tune the threshold voltage (Vₜ) of transistors 102A-102C. In some embodiments, gate electrode 112 for NFET and PFET devices can have the same work-function metal. In some embodiments, gate electrode 112 for NFET and PFET devices can have different work-function metals. In some embodiments, transistors 102A-102C can include any number of work function metal layers for Vₜ tuning (e.g., ultra-low Vₜ, low Vₜ, and standard Vₜ).

In some embodiments, NFETs 102A-102C can include n-type work function metal layers. The n-type work function metal layers can include aluminum, titanium aluminum, titanium aluminum carbon, tantalum aluminum, tantalum aluminum carbon, tantalum silicon carbide, hafnium carbide, silicon, titanium nitride, titanium silicon nitride, or other suitable work function metals. In some embodiments, PFETs 102A-102C can include p-type work function metal layers. The p-type work function metal layers can include titanium nitride, titanium silicon nitride, tantalum nitride, tungsten carbon nitride, tungsten, molybdenum, or other suitable work function metals. In some embodiments, the work function metal layers can include a single metal layer or a stack of metal layers. The stack of metal layers can include work function metals having work-function values equal to or different from each other. In some embodiments, the metal fill can include titanium, tantalum, aluminum, cobalt, tungsten, nickel, ruthenium, or other suitable conductive materials.

Referring to FIGS. 1 and 2, gate spacers 114 can be disposed on sidewalls of gate structures 120 and sidewall spacers 107 can be disposed on sidewalls of fin structures 108. Gate spacers 114 and sidewall spacers 107 can include insulating materials, such as silicon oxide, silicon nitride, silicon oxynitride, silicon carbonitride, silicon oxycarbide, silicon oxycarbonitride, a low-k material, and a combination thereof. In some embodiments, gate spacers 114 and sidewall spacers 107 can include the same insulating material. In some embodiments, gate spacers 114 and sidewall spacers 107 can include different insulating materials. Gate spacers 114 and sidewall spacers 107 can include a single layer or a stack of insulating layers. Gate spacers 114 and sidewall spacers 107 can have a low-k material with a dielectric constant less than about 3.9 (e.g., about 3.5, about 3.0, or about 2.8).

Referring to FIGS. 1 and 2, gate capping structures 126 can be disposed on gate structures 120 and gate spacers 114 and configured to protect underlying structures and/or layers during processing of semiconductor device 100. For example, gate capping structures 126 can act as an etch stop layer during the formation of S/D contact structures 130 on S/D structures 110. Gate capping structures 126 can include one or more insulating materials. In some embodiments, the insulating materials can include silicon nitride, silicon oxide, silicon oxynitride, silicon carbide, silicon carbonitride, aluminum oxide, or other suitable materials. In some embodiments, gate capping structures 126 can have a thickness 126t along a Z-axis ranging from about 5 nm to about 25 nm.

In some embodiments, as shown in FIG. 2, gate capping structures 126 can include a bottom portion 126-1 on top surfaces of gate structures 120 and gate spacers 114 and a top portion 126-2 on bottom portion 126-1. In some embodiments, top portion 126-2 can extend wider than bottom portion 126-1. In some embodiments, bottom portion 126-1 can have a first width along an X-axis and top portion 126-2 can have a second width along an X-axis. In some embodiments, the second width can be greater than the first width. In some embodiments, top portion 126-2 of gate capping structures 126 can include implanted ions, such as germanium and argon. In some embodiments, a dose of the implanted ions can range from about 1E10 cm⁻² to about 1E30 cm⁻². In some embodiments, as shown in FIG. 2, the bulged top portion 126-2 can push liner 232 towards spacer layer 234 to seal air spacers 236.

S/D structures 110 can be disposed on fin structures 108. In some embodiments, S/D structures 110 can be in contact with the channel regions of fin structures 108 and on opposing sides of gate structures 120. S/D structures 110 can function as S/D regions of transistors 102A-102C. In some embodiments, S/D structures 110 can have any geometric shape, such as a polygon, an ellipse, and a circle. In some embodiments, S/D structures 110 can include an epitaxially-grown semiconductor material, such as silicon (e.g., the same material as substrate 104). In some embodiments, the epitaxially-grown semiconductor material can include an epitaxially-grown semiconductor material different from the material of substrate 104, such as silicon germanium, and imparts a strain on the channel regions under gate structures 120. Since the lattice constant of such epitaxially-grown semiconductor material is different from the material of substrate 104, the channel regions are strained to increase carrier mobility in the channel regions of semiconductor device 100. The epitaxially-grown semiconductor material can include: (i) a semiconductor material, such as germanium and silicon; (ii) a compound semiconductor material, such as gallium arsenide and aluminum gallium arsenide; or (iii) a semiconductor alloy, such as silicon germanium and gallium arsenide phosphide.

In some embodiments, S/D structures 110 can include silicon and can be in-situ doped during an epitaxial growth process using n-type dopants, such as phosphorus and arsenic. In some embodiments, S/D structures 110 can include silicon, silicon germanium, germanium, or III-V materials (e.g., indium antimonide, gallium antimonide, or indium gallium antimonide) and can be in-situ doped during an epitaxial growth process using p-type dopants, such as boron, indium, and gallium. In some embodiments, S/D structures 110 can include one or more epitaxial layers, where each epitaxial layer can have different compositions. In some embodiments, S/D structures 110 can have a width along an X-axis ranging from about 20 nm to about 40 nm. In some embodiments, S/D structures 110 can have a height along a Z-axis ranging from about 50 nm to about 100 nm.

Referring to FIGS. 1 and 2, semiconductor device 100 can further include etch stop layer (ESL) 116, interlayer dielectric (ILD) layer 118, S/D contact structures 130, liner 232, air spacers 236, and spacer layer 234.

As shown in FIGS. 1 and 2, ESL 116 can be disposed on STI regions 106, S/D structures 110, and sidewalls of gate spacers 114 and sidewall spacers 107. ESL 116 can be configured to protect STI regions 106, S/D structures 110, and gate structures 120 during the formation of S/D contact structures 130 on S/D structures 110. In some embodiments, ESL 116 can include, for example, silicon oxide, silicon nitride, silicon oxynitride, silicon carbide, silicon carbonitride, boron nitride, silicon boron nitride, silicon carbon boron nitride, or a combination thereof.

ILD layer 118 can be disposed on ESL 116 over S/D structures 110 and STI regions 106. ILD layer 118 can include a dielectric material deposited using a deposition method suitable for flowable dielectric materials. For example, flowable silicon oxide can be deposited using flowable chemical vapor deposition (FCVD). In some embodiments, the dielectric material can include silicon oxide.

S/D contact structures 130 can be disposed on S/D structures 110. In some embodiments, S/D contact structures 130 can include a silicide layer and a metal contact. In some embodiments, the silicide layer can include metal silicide and can provide a lower resistance interface between the metal contact and S/D structures 110. Examples of metal used for forming the metal silicide include cobalt, titanium, and nickel. In some embodiments, the metal contact can include conductive materials, such as tungsten, aluminum, and cobalt. In some embodiments, as shown in FIG. 1, S/D contact structures 130 can extend through ILD layer 118 and into S/D structures 110. In some embodiments, S/D contact structures 130 can extend below top surfaces of S/D structures 110 for a distance ranging from about 5 nm to about 20 nm. In some embodiments, S/D contact structures 130 can have a width 130w along an X-axis ranging from about 5 nm to about 50 nm.

In some embodiments, liner 232 can be disposed on top surfaces of S/D structures 110 and sidewall surfaces of gate spacers 114 and gate capping structures 126. In some embodiments, liner 232 can include a dielectric material, a semiconductor material, a metal, or other suitable materials to isolate air spacers 236 from S/D structures 110. In some embodiments, liner 232 can protect S/D structures 110 during the formation of air spacers 236. In some embodiments, liner 232 can include silicon nitride, silicon oxide, silicon, or titanium nitride. In some embodiments, liner 232 can have a thickness 232t ranging from about 0.5 nm to about 5 nm. In some embodiments, a ratio of thickness 232t to width 130w can range from about 0.01 to about 0.2. If thickness 232t is less than about 0.5 nm or the ratio is less than about 0.01, liner 232 may not protect S/D structures 110. If thickness 232t is greater than about 5 nm or the ratio is greater than about 0.2, the contact resistance between S/D contact structures 130 and S/D structures 110 may increase.

In some embodiments, spacer layer 234 can be disposed on sidewall surfaces of S/D contact structures 130 and in contact with the top surfaces of S/D structures 110. In some embodiments, spacer layer 234 can include a dielectric material, such as silicon nitride, to protect S/D contact structures 130. In some embodiments, spacer layer 234 can have a thickness 234t ranging from about 0.5 nm to about 5 nm. In some embodiments, top portions of spacer layer 234 and liner 232 can be pushed together by the bulged top portion 126-2 of gate capping structures 126 to seal air spacers 236. In some embodiments, the top portions of spacer layer 234 and liner 232 can merge and the merged top portions can be above top surfaces of gate structures 120. In some embodiments, the merged top portion of liner 232 can be directly above air spacers 236. In some embodiments, the merged top portions of spacer layer 234 and liner 232 can have a height 232h ranging from about 2 nm to about 25 nm. If height 232h is less than about 2 nm, air spacers 236 may not be sealed. If height 232h is greater than about 25 nm, the dimensions of air spacers 236 may be reduced and the reliability of semiconductor device 100 may decrease. In some embodiments, height 232h of the merged top portions can be less than thickness 126t of gate capping structures 126.

In some embodiments, as shown in FIG. 2, air spacers 236 can be disposed between gate structures 120 and S/D contact structures 130 and enclosed by liner 232 and spacer layer 234. In some embodiments, air spacers 236 can be filled with air and can have a dielectric constant of about 1. In some embodiments, air spacers 236 can reduce the capacitance between gate structures 120 and S/D contact structures 130 and improve the reliability of semiconductor device 100. In some embodiments, air spacers 236 can have a width 236w along an X-axis ranging from about 0.5 nm to about 5 nm. In some embodiments, a ratio of width 236w to width 130w can range from about 0.01 to about 0.2. If width 236w is less than about 0.5 nm or the ratio is less than about 0.01, the capacitance between gate structures 120 and S/D contact structures 130 may increase and device performance of semiconductor device 100 may decrease. If thickness 232t is greater than about 5 nm or the ratio is greater than about 0.2, the contact resistance between S/D contact structures 130 and S/D structures 110 may increase.

In some embodiments, air spacers 236 can be separated from S/D structures 110 by liner 232. In some embodiments, a distance 236d1 between bottom surfaces of air spacers 236 and the top surfaces of S/D structures 110 can range from about 0.5 nm to about 5 nm. If distance 236d1 is less than about 0.5 nm, liner 232 may not protect S/D structures 110 during the formation of air spacers 236 and device yield may decrease. If distance 236d1 is greater than about 5 nm, the dimensions of air spacers 236 may be reduced and the reliability of semiconductor device 100 may decrease. In some embodiments, top surfaces of air spacers 236 can be above top surfaces of gate structures 120 to reduce the capacitance between gate structures 120 and S/D contact structures 130. In some embodiments, a distance 236d2 between top surfaces of air spacers 236 and top surfaces of gate structures 120 can range from about 0.5 nm to about 15 nm. In some embodiments, a ratio of distance 236d2 to thickness 126t can range from about 0.02 to about 0.8. If distance 236d2 is less than about 0.5 nm or the ratio is less than about 0.02, the capacitance between gate structures 120 and S/D contact structures 130 may increase. If distance 236d2 is greater than about 15 nm or the ratio is greater than about 0.8, liner 232 and spacer layer 234 may not seal air spacers 236.

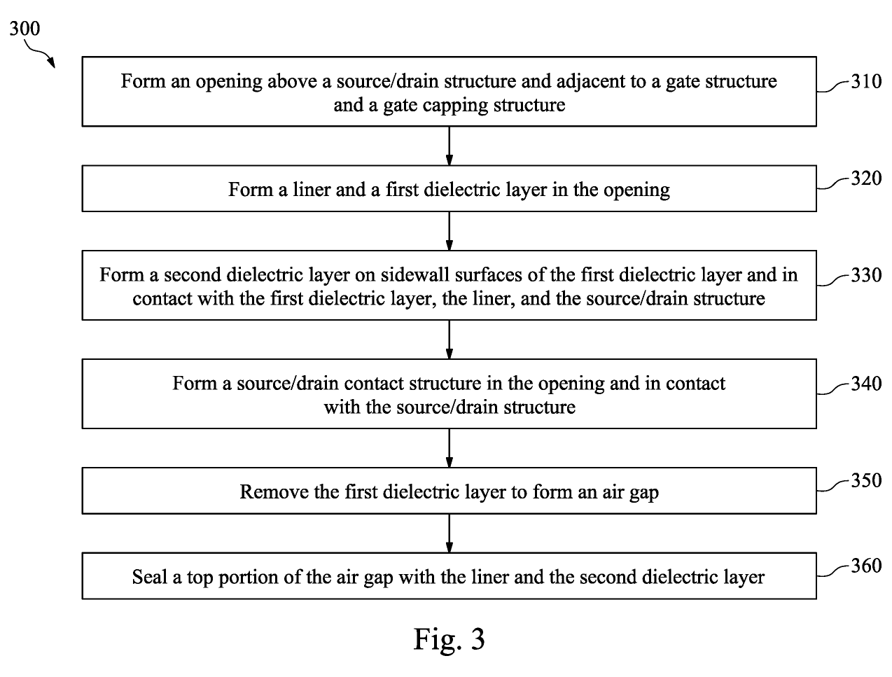

FIG. 3 is a flow diagram of a method 300 for fabricating semiconductor device 100 having an air spacer with a liner protecting a source/drain structure, in accordance with some embodiments. Method 300 may not be limited to nanostructure transistor devices and can be applicable to other devices that would benefit from the air spacer with a liner protecting a source/drain structure. Additional fabrication operations may be performed between various operations of method 300 and may be omitted merely for clarity and ease of description. Additional processes can be provided before, during, and/or after method 300; one or more of these additional processes are briefly described herein. Moreover, not all operations may be needed to perform the disclosure provided herein. Additionally, some of the operations may be performed simultaneously or in a different order than shown in FIG. 3. In some embodiments, one or more other operations may be performed in addition to or in place of the presently-described operations.

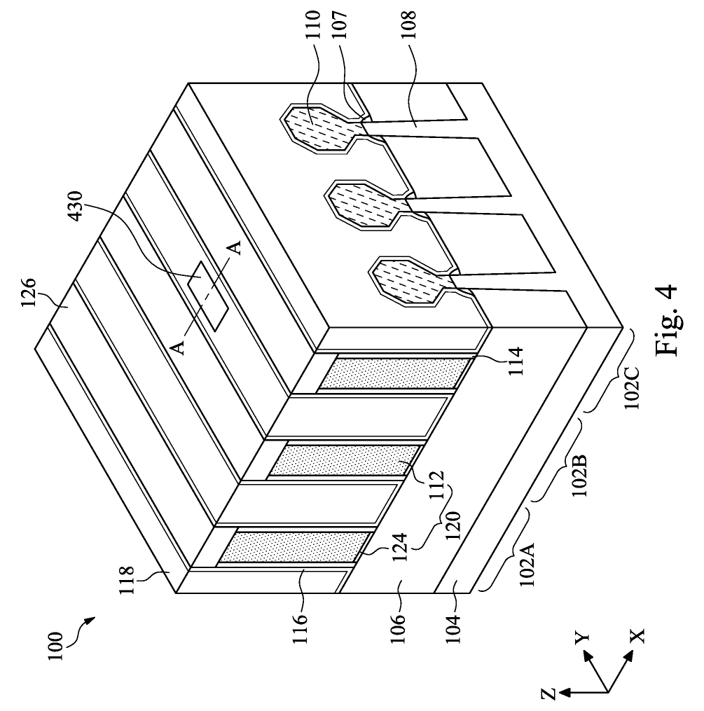

For illustrative purposes, the operations illustrated in FIG. 3 will be described with reference to the example fabrication process for fabricating semiconductor device 100 as illustrated in FIGS. 4-11. FIGS. 4-11 illustrate partial isometric and cross-sectional views of semiconductor device 100 having an air spacer with a liner protecting a source/drain structure at various stages of its fabrication, in accordance with some embodiments. In some embodiments, elements in FIGS. 4-11 with the same annotations as elements in FIGS. 1 and 2 are described above.

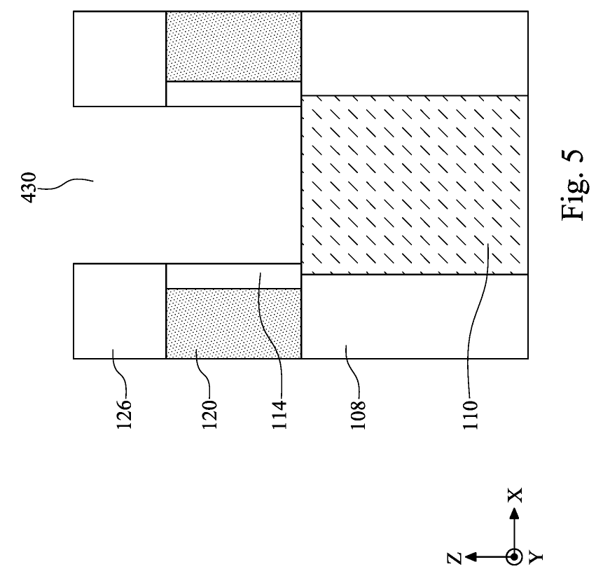

In referring to FIG. 3, method 300 begins with operation 310 and the process of forming an opening above a source/drain structure and adjacent to a gate structure and a gate capping structure. For example, as shown in FIGS. 4 and 5. Opening 430 can be formed above S/D structures 110 and adjacent to gate structures 120 and gate capping structures 126. In some embodiments, the formation of opening 430 can include a patterning process and a selective etching process to remove ILD layer 118 and ESL 116 on S/D structures 110. In some embodiments, opening 430 can expose top surfaces of S/D structures 110 and sidewall surfaces of gate spacers 114 and gate capping structures 126.

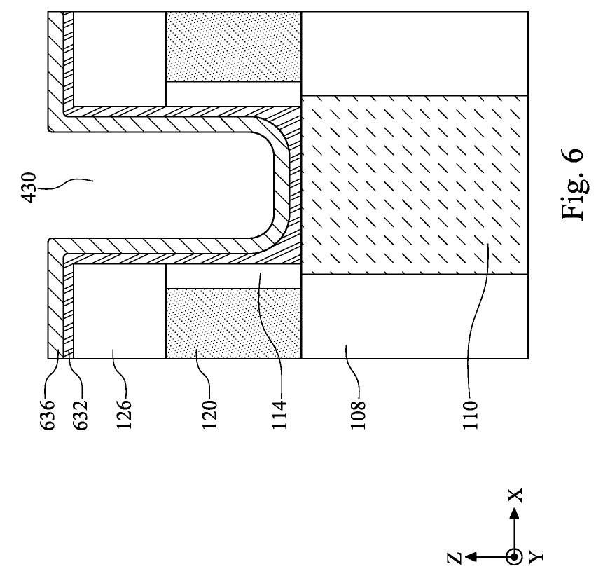

Referring to FIG. 3, in operation 320, a liner and a first dielectric layer can be formed in the opening. For example, as shown in FIG. 6, liner 632 and first dielectric layer 636 can be formed in opening 430. In some embodiments, liner 632 can be blanket deposited in the opening and on gate capping structures 126 by atomic layer deposition (ALD), chemical vapor deposition (CVD), or other suitable deposition methods. In some embodiments, liner 632 can cover top surfaces of S/D structures 110, sidewall surfaces of gate spacers 114, and top and sidewall surfaces of gate capping structures 126. In some embodiments, liner 632 can include a dielectric material, a semiconductor material, a metal, or other suitable materials. In some embodiments, liner 632 can include silicon nitride, silicon oxide, silicon, or titanium nitride.

In some embodiments, first dielectric layer 636 can be blanket deposited on liner 632 and in opening 430 by ALD, CVD, or other suitable deposition methods. In some embodiments, first dielectric layer 636 can include silicon oxide, silicon nitride, silicon oxynitride, silicon carbonitride, silicon oxycarbonitride, or other suitable dielectric materials. In some embodiments, first dielectric layer 636 can be a sacrificial dielectric layer removed in subsequent processes. In some embodiments, a selectivity between first dielectric layer 636 and liner 632 can range from about 10 to about 100 for subsequent removal of first dielectric layer 636.

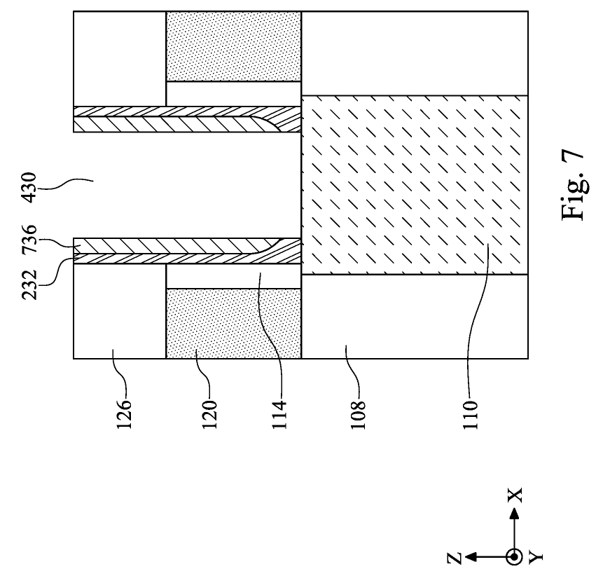

In some embodiments, the deposition of first dielectric layer 636 can be followed by a directional etch, as shown in FIG. 7. In some embodiments, the directional etch can remove liner 632 and first dielectric layer 636 from top surfaces of S/D structures 110 and gate capping structures 126. In some embodiments, after the directional etch, liner 232 and first dielectric layer 736 can remain on sidewall surfaces opening 430. In some embodiments, liner 232 can be in contact with the top surfaces of S/D structures 110. First dielectric layer 736 can be separated from S/D structures 110 by liner 232.

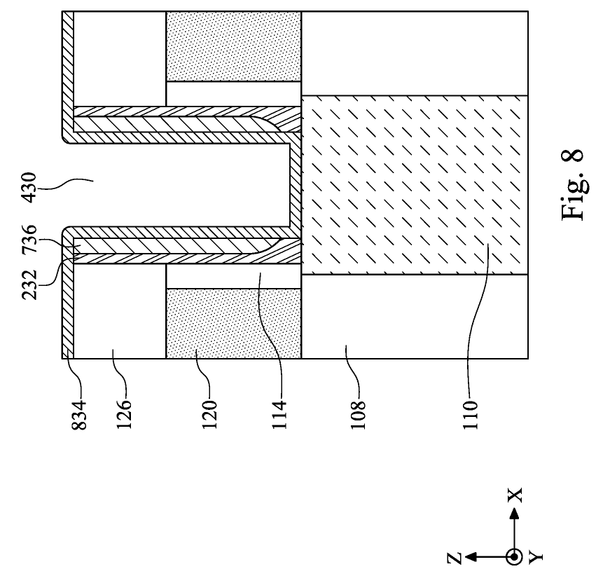

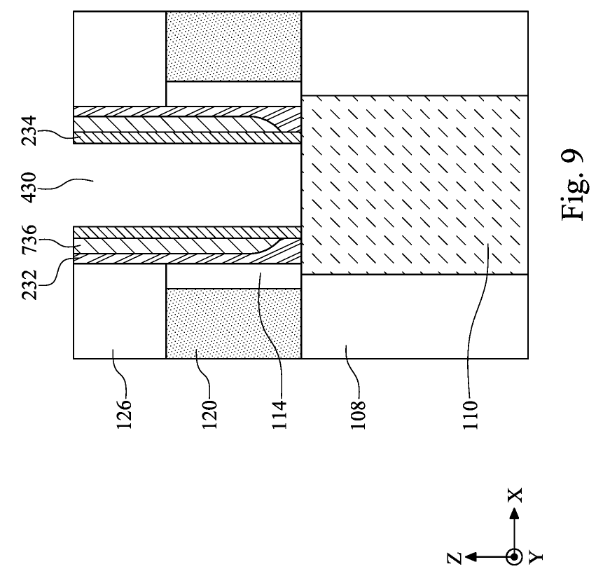

Referring to FIG. 3, in operation 330, a second dielectric layer can be formed on sidewall surfaces of the first dielectric layer. The second dielectric layer can be in contact with the first dielectric layer, the liner, and the source/drain structure. For example, as shown in FIGS. 8 and 9, spacer layer 234 can be formed on sidewall surfaces of first dielectric layer 736. Spacer layer 234 can be in contact with first dielectric layer 736, liner 232, and S/D structures 110.

In some embodiments, the formation of spacer layer 234 can include blanket deposition of second dielectric layer 834 in opening 430 and directional etching of second dielectric layer 834. In some embodiments, as shown in FIG. 8, second dielectric layer 834 can be blanket deposited in opening 430 and on top surfaces of gate capping structures 126 by ALD, CVD, or other suitable deposition methods. In some embodiments, second dielectric layer 834 can include silicon nitride or other suitable dielectric materials. In some embodiments, as shown in FIG. 9, a directional etch can remove second dielectric layer 834 from top surfaces of S/D structures 110 and gate capping structures 126. After the directional etch, the remaining portion of second dielectric layer 834 can form spacer layer 234 on sidewall surfaces of first dielectric layer 736 in opening 430. In some embodiments, spacer layer 234 can protect subsequently-formed S/D contact structures 130. In some embodiments, a selectivity between first dielectric layer 736 and spacer layer 234 can range from about 10 to about 100 to protect S/D contact structures 130.

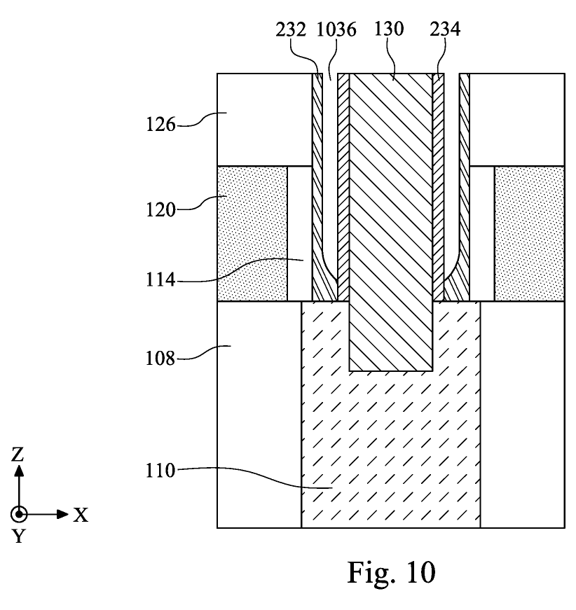

Referring to FIG. 3, in operation 340, a source/drain contact structure can be formed in the opening and in contact with the source/drain structure. For example, as shown in FIG. 10, S/D contact structures 130 can be formed in opening 430. S/D contact structures 130 can be in contact with S/D structures 110. In some embodiments, the formation of S/D contact structures 130 can include blanket deposition of a conductive material and a chemical mechanical polishing (CMP) process to remove the conductive material outside opening 430.

In some embodiments, a conductive material can be blanket deposited in opening 430 and on top surfaces of gate capping structures 126 by CVD, plating, or other suitable deposition methods. In some embodiments, the conductive material can include tungsten, aluminum, or cobalt. In some embodiments, a metal silicide layer can be formed on S/D contact structures 130 before the blanket deposition of the conductive material. Examples of metal used to form the metal silicide include cobalt, titanium, and nickel.

In some embodiments, the CMP process can remove the conductive material on top surfaces of gate capping structures 126, liner 232, first dielectric layer 736, and spacer layer 234. In some embodiments, gate capping structures 126 can act as an etch stop layer for the CMP process. After the CMP process, top surfaces of S/D contact structures 130, gate capping structures 126, liner 232, first dielectric layer 736, and spacer layer 234 can be co-planar.

Referring to FIG. 3, in operation 350, the first dielectric layer can be removed to form an air gap. For example, as shown in FIG. 10, first dielectric layer 736 can be removed and an air gap 1036 can be formed between liner 232 and spacer layer 234. In some embodiments, first dielectric layer 736 can be removed by a selective etching process. In some embodiments, the selective etching process can remove first dielectric layer 736 without removing liner 232 or spacer layer 234. In some embodiments, the selectivity of first dielectric layer 736 to liner 232 and spacer layer 234 can range from about 10 to about 100. If the selectivity is less than about 10, liner 232 and spacer layer 234 may be removed during the removal of first dielectric layer 736. If the selectivity is greater than about 100, the cost of the selective etching process may increase. With liner 232 protecting S/D structures 110, S/D structures 110 may not be damaged by the selective etching process and yield of semiconductor device 100 can increase.

In some embodiments, the selective etching process can include a dry etching process. In some embodiments, the dry etching process can use a fluorine- or chlorine-based etchant mixed with hydrogen or oxygen. In some embodiments, the flow rate of the fluorine- or chlorine-based etchant used in the dry etching process can range from about 5 sccm to about 200 sccm. In some embodiments, the dry etching process can be performed at a pressure ranging from about 1 mTorr to about 100 mTorr. In some embodiments, the dry etching process can be performed with a plasma power ranging from about 50 W to about 250 W. After the selective etching process, first dielectric layer 736 can be removed and air gap 1036 can be formed between liner 232 and spacer layer 234.

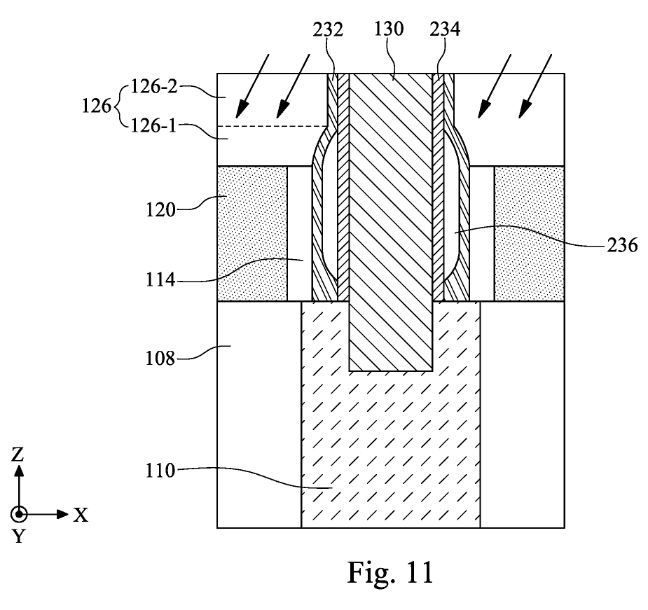

Referring to FIG. 3, in operation 360, a top portion of the air gap is sealed by the liner and the second dielectric layer. For example, as shown in FIG. 11, the top portion of air gap 1036 can be sealed by liner 232 and spacer layer 234 to form air spacers 236. In some embodiments, an ion implant process can be performed on gate capping structures 126 and S/D contact structures 130. In some embodiments, top portion 126-2 of gate capping structures 126 can be bulged after the ion implant process. The bulged top portion 126-2 can push liner 232 and spacer layer 234 together to seal air spacers 236. In some embodiments, after the ion implant process, liner 232 can be attached to and/or merged with spacer layer 234 at the top portion of air gap 1036. In some embodiments, the implant ion can include larger ions in IIIA, IVA, VA, VIA, VIIA, or VIIIA element groups, such as germanium and argon. In some embodiments, the implant energy of the implant ion can range from about 0.1 keV to about 30 keV. In some embodiments, the implant angle between the implant ion and a normal direction along a Z-axis can range from 0 degree to about 90 degrees. In some embodiments, after the ion implant process, top portion 126-2 can be expanded wider than bottom portion 126-1 of gate capping structures 126. In some embodiments, the dimensions of S/D contact structures 130, liner 232, and spacer layer 234 may not be substantially changed by the ion implant process.

Various embodiments in the present disclosure provide methods for forming air spacers 236 with liner 232 protecting S/D structures 110 in semiconductor device 100. In some embodiments, semiconductor device 100 can include fin structures 108 on substrate 104. S/D structures 110 can be in contact with fin structures 108 and gate structures 120 can be disposed on fin structures 108. Gate spacers 114 can be disposed on sidewall surfaces of gate structures 120. Gate capping structures 126 can be disposed on gate structures 120. Liner 232 can be disposed on top surfaces of S/D structures 110 and sidewall surfaces of gate spacers 114 and gate capping structures 126. S/D contact structures 130 can be disposed on S/D structures 110 and adjacent to gate structures 120. Spacer layer 234 can be disposed on sidewall surfaces of S/D contact structures 130. Liner 232 and spacer layer 234 can enclose air spacer 236 between gate structures 120 and S/D contact structures 130. In some embodiments, liner 232 can separate air spacers 236 from S/D structures 110 to avoid damage to S/D structures 110 during the formation of air spacer 236. In some embodiments, with liner 232 protecting S/D structures 110, both the reliability and the yield of semiconductor device 100 can be improved.

In some embodiments, a semiconductor device includes a source/drain (S/D) structure on a substrate, a gate structure on the substrate and adjacent to the S/D structure, a gate capping structure on the gate structure, a contact structure on the S/D structure and adjacent to the gate structure, a liner on sidewall surfaces of the gate capping structure and top surfaces of the S/D structure, and a spacer layer on sidewall surfaces of the contact structure. An air gap is enclosed by the spacer layer and the liner.

In some embodiments, a semiconductor device includes a channel structure on a substrate, a source/drain (S/D) structure in contact with the channel structure, a gate structure on the channel structure, a gate spacer on sidewall surfaces of the gate structure, a contact structure on the S/D structure and adjacent to the gate structure, a liner on top surfaces of the S/D structure and sidewall surfaces of the gate spacer, and a spacer layer on sidewall surfaces of the contact structure. The liner and the spacer layer enclose an air gap between the gate structure and the contact structure.

In some embodiments, a method includes forming an opening above a source/drain (S/D) structure and adjacent to a gate structure and a gate capping structure. The gate capping structure is on the gate structure. The method further includes forming a liner and a first dielectric layer in the opening. The first dielectric layer is separated from the S/D structure by the liner. The method further includes forming a second dielectric layer on sidewall surfaces of the first dielectric layer. The second dielectric layer is in contact with the first dielectric layer, the liner, and the S/D structure. The method further includes forming a S/D contact structure in the opening and in contact with the S/D structure, removing the first dielectric layer to form an air gap, and sealing a top portion of the air gap. The air gap is enclosed by the second dielectric layer and the liner.

It is to be appreciated that the Detailed Description section, and not the Abstract of the Disclosure section, is intended to be used to interpret the claims. The Abstract of the Disclosure section may set forth one or more but not all possible embodiments of the present disclosure as contemplated by the inventor(s), and thus, are not intended to limit the subjoined claims in any way.

The foregoing disclosure outlines features of several embodiments so that those skilled in the art may better understand the aspects of the present disclosure. Those skilled in the art will appreciate that they may readily use the present disclosure as a basis for designing or modifying other processes and structures for carrying out the same purposes and/or achieving the same advantages of the embodiments introduced herein. Those skilled in the art will also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a source/drain (S/D) structure on a substrate;
a gate structure on the substrate and adjacent to the S/D structure;
a gate capping structure on the gate structure;
a contact structure on the S/D structure and adjacent to the gate structure;
a liner on sidewall surfaces of the gate capping structure and top surfaces of the S/D structure; and
a spacer layer on sidewall surfaces of the contact structure, wherein an air gap is enclosed by the spacer layer and the liner.

2. The semiconductor device of claim 1, wherein the spacer layer is in contact with the S/D structure and the liner.

3. The semiconductor device of claim 1, wherein the air gap is separated from the S/D structure by the liner.

4. The semiconductor device of claim 1, wherein top surfaces of the spacer layer, the liner, the contact structure, and the gate capping structure are co-planar.

5. The semiconductor device of claim 1, further comprising a gate spacer on sidewall surfaces of the gate structure, wherein the liner is in contact with sidewall surfaces of the gate spacer.

6. The semiconductor device of claim 1, wherein a top width of the gate capping structure is greater than a bottom width of the gate capping structure.

7. The semiconductor device of claim 1, wherein a portion of the spacer layer and a portion of the liner merge above the air gap, and wherein a height of the merged portion of the liner ranges from about 2 nm to about 25 nm.

8. The semiconductor device of claim 7, wherein the height of the merged portion of the liner is less than a thickness of the gate capping structure.

9. The semiconductor device of claim 1, wherein a ratio of a width of the air gap to a width of the contact structure ranges from about 1 % to about 20 %.

10. A semiconductor device, comprising:
a channel structure on a substrate;
a source/drain (S/D) structure in contact with the channel structure;
a gate structure on the channel structure;
a gate spacer on sidewall surfaces of the gate structure;
a contact structure on the S/D structure and adjacent to the gate structure;
a liner on top surfaces of the S/D structure and sidewall surfaces of the gate spacer; and
a spacer layer on sidewall surfaces of the contact structure, wherein the liner and the spacer layer enclose an air gap between the gate structure and the contact structure.

11. The semiconductor device of claim 10, wherein the spacer layer is in contact with the S/D structure and the liner.

12. The semiconductor device of claim 10, wherein the air gap is separated from the S/D structure by the liner.

13. The semiconductor device of claim 10, wherein top surfaces of the spacer layer, the liner, and the contact structure are co-planar.

14. The semiconductor device of claim 10, wherein a top portion of the liner is directly above the air gap.

15. The semiconductor device of claim 10, wherein:
a portion of the spacer layer and a portion of the liner merge above the air gap;
a height of the merged portion of the liner ranges from about 2 nm to about 25 nm; and
the merged portion of the liner is above a top surface of the gate structure.

16. A method, comprising:
forming an opening above a source/drain (S/D) structure and adjacent to a gate structure and a gate capping structure, wherein the gate capping structure is on the gate structure;
forming a liner and a first dielectric layer in the opening, wherein the first dielectric layer is separated from the S/D structure by the liner;
forming a second dielectric layer on sidewall surfaces of the first dielectric layer, wherein the second dielectric layer is in contact with the first dielectric layer, the liner, and the S/D structure;
forming a S/D contact structure in the opening and in contact with the S/D structure;
removing the first dielectric layer to form an air gap; and
sealing a top portion of the air gap, wherein the air gap is enclosed by the second dielectric layer and the liner.

17. The method of claim 16, wherein forming the liner and the first dielectric layer in the opening comprises:
depositing the liner in the opening and on the gate capping structure;
depositing the first dielectric layer on the liner; and
removing the liner and the first dielectric layer in the opening and on the gate capping structure with a directional etching process.

18. The method of claim 16, wherein forming the second dielectric layer on the sidewall surfaces of the first dielectric layer comprises:
depositing the second dielectric layer in the opening and on the gate capping structure; and
removing the second dielectric layer in the opening and on the gate capping structure with a directional etching process.

19. The method of claim 16, wherein forming the S/D contact structure in the opening comprises:
depositing a conductive material in the opening and on the gate capping structure; and
planarizing top surfaces of the conductive material, the liner, the first and second dielectric layers, and the gate capping structure with a chemical mechanical polishing process.

20. The method of claim 16, wherein sealing the top portion of the air gap comprises implanting ions into the gate capping structure to expand the gate capping structure such that the liner is attached to the second dielectric layer at the top portion of the air gap.
